(19) United States
(12) Patent Application Publication
(10) Pub. No.: US 2006/0214151 A1
(43) Pub. Date: Sep. 28, 2006

(54) Light-emitting element and laser apparatus using the light-emitting element

(75) Inventors: Hiroko Abe, Setagaya (JP); Mikio Yukawa, Atsugi (JP); Ryoji Nomura, Yamato (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/376,321

(22) Filed: Mar. 16, 2006

(30) Foreign Application Priority Data
Mar. 24, 2005 (JP) 2005-086101

(51) Int. Cl. H01L 29/06

(52) U.S. Cl. 257/13

(57) ABSTRACT

It is an object of the present invention to provide a light-emitting element in which an inverted distribution state can be formed by exciting an organic compound with current at low current density, and moreover to provide a laser oscillator of a current excitation type using an organic compound as a laser medium. In a light-emitting element of the present invention, a molecule existing in a ground state is not directly excited by external energy but is excited by current fed to a first layer and a second layer which are provided adjacently so that ion species are accumulated in a region of the first layer that is in contact with the second layer.

### BACKGROUND OF THE INVENTION

1. Field of the Invention

The present invention relates to a light-emitting element producing stimulated emission by current excitation, and also relates to a laser apparatus using the light-emitting element.

2. Description of the Related Art

Laser light has monochromaticity, high coherence, and high directivity, and has played an essential role in the fields of optical communication technologies, optical recording technologies, optical information processing technologies, and the like. Apparatuses for producing laser light, i.e., laser apparatuses are mainly categorized into solid-state lasers, dye lasers, and gas lasers according to their laser media. Among these lasers, semiconductor lasers as one type of the solid-state lasers have rapidly developed in recent years. Semiconductor lasers have several advantages: (1) since an apparatus can be made compact, a semiconductor laser can be easily combined with another component such as an optical module to be connected to fiber optics; (2) since laser light is obtained by current excitation, instantaneous oscillation is possible by feeding current and its output can be adjusted by the amount of current and stable output can be obtained; and (3) since the semiconductor laser can be manufactured by transferring a semiconductor manufacturing process that has already established technically, mass production is possible. Moreover, another big advantage is that an output wavelength can be converted by changing a semiconductor medium.

A semiconductor laser including an inorganic compound semiconductor has a P-type semiconductor layer 1003, an N-type semiconductor layer 1004, and an active layer 1005 for emitting light, which are sandwiched between an electrode 1001 and an electrode 1002 as shown in FIG. 9. As the active layer 1005, a compound semiconductor such as InGaAsP, GaAs, or InGaN is often used. The semiconductor laser is manufactured by sandwiching this active layer 1005 between the N-type semiconductor layer 1004 and the P-type semiconductor layer 1003 which are referred to as cladding layers. As a compound semiconductor used for the cladding layers, InP, AlGaAs, ZnSSe, GaN, or the like is given. Holes are injected from the P-type semiconductor layer 1003 while electrons are injected from the N-type semiconductor layer 1004, and then these carriers reach the active layer 1005. When the holes and electrons are recombined at the active layer 1005, light corresponding to an energy difference between a valence band and a conduction band is generated. Most of the generated light is confined within the active layer 1005 and outputted from a cleavage plane. The reflectivity of the cleavage plane depends on the refractive index between the active layer 1005 and the air. For example, in the case of using GaAs for the active layer, light is reflected by approximately 30% and returns to the active layer 1005. The reflected light is amplified while being reflected at two cleavage planes of the active layer 1005, and only light that has a wavelength determined by the length of the active layer is amplified. Here, when the current value is increased, inverted distribution is formed at certain current density. The current density at this time is referred to as a threshold, and light whose amplitude is amplified by stimulated emission after this threshold is emitted from the cleavage plane as laser light.

As thus described, the semiconductor lasers which have been developed so far include inorganic semiconductors, and are referred to as inorganic semiconductor lasers. In contrast, development of lasers using organic compounds as their laser media (such lasers are referred to as organic lasers) has been very difficult and not yet put into practical use. However, if the organic lasers are put into practical use, the organic lasers can offer advantages that cannot be provided by the inorganic semiconductor lasers. For example, a flexible laser can be manufactured based on flexibility of a material, simplification of a manufacturing process as well as cost reduction are possible, and a variety of manufacturing processes are applicable (evaporation, spin coating, printing, dip coating, or the like can be applied), and so on.

A main factor that has interrupted the development of the organic lasers is that it has been difficult to form an inverted distribution state which is necessary for laser oscillation in the case of using an organic compound.

As disclosed in Non-Patent Document 1 (Kozlov, V. G et al. Applied Physics Letters, 1998, Vol. 72, p. 144 to 146), 5 μJ/cm² of light energy density is required to oscillate laser light with the use of an organic compound (in other words, to form an inverted distribution state). In order to obtain the energy corresponding to this light energy density by current injection, current with current density as high as several thousand A/cm² is required. However, if current with current density as high as several thousand A/cm² is fed into an organic compound, an element will be destroyed. Therefore, in order to achieve laser oscillation of a current excitation type using an organic compound as a laser medium, it has been necessary to develop a technique for forming an inverted distribution state with low current density.

### SUMMARY OF THE INVENTION

The present invention has been made in view of the above problem, and it is an object of the present invention to provide a light-emitting element in which an inverted distribution state can be formed by exciting an organic compound with current at low current density. It is another object of the present invention to provide a laser oscillator of a current excitation type using an organic compound as a laser medium (that is, a laser apparatus).

In a conventional laser element, inverted distribution is obtained by exciting ground-state molecules into excited-state molecules by external energy, thereby making the number of ground-state molecules larger than that of excited-state molecules. In contrast, in the present invention, inverted distribution is formed in such a way that a ground-state molecule is made in a state having a carrier electrochemically to decrease the number of ground-state molecules relatively, thereby making the number of excited-state molecules larger than that of ground-state molecules. In order to form such inverted distribution, a plurality of layers are formed between a pair of electrodes.

A structure of a light-emitting element according to the present invention will be hereinafter described.

A light-emitting element of the present invention includes at least a first layer and a second layer between a pair of electrodes, wherein the first layer and the second layer are provided adjacently so that ion species are accumulated in a region of the first layer that is in contact with the second region when holes or electrons are injected into the first layer and the second layer.

Specifically, a light-emitting element of the present invention includes a first layer and a second layer which are adjacent to each other, wherein energy barriers exist between a LUMO (Lowest Unoccupied Molecular Orbital) level of the first layer and a LUMO level of the second layer, and between a HOMO (Highest Occupied Molecular Orbital) level of the first layer and a HOMO level of the second layer. Moreover, the energy barrier between the HOMO levels is higher than that between the LUMO levels.

In a light-emitting element of the present invention having another mode, an inverted distribution state is formed in such a way that a proportion of excited-state molecules is made larger than that of ground-state molecules by electrochemically decreasing a proportion of molecules existing in a ground state in a region of the first layer that is in contact with the second layer.

A light-emitting element of the present invention having another mode includes a first energy barrier for blocking the movement of holes from the first layer to the second layer and a second energy barrier for blocking the movement of electrons from the second layer to the first layer. Moreover, the first energy barrier is higher than the second energy barrier.

In a light-emitting element of the present invention having another mode, the polarity of carriers to be transported preferentially is different for each of the first layer and the second layer. The HOMO level of the first layer is higher than the HOMO level of the second layer, while the LUMO level of the first layer is higher than the LUMO level of the second layer. Moreover, the first layer has a higher hole-transporting property than electron-transporting property, while the second layer has a higher electron-transporting property than hole-transporting property.

An absolute value of the difference between the HOMO levels of the first layer and the second layer is preferably 0.5 eV or more, and more preferably 0.5 eV or more and less than 3.0 eV. Moreover, an absolute value of the difference between the LUMO levels of the first layer and the second layer is preferably 0.1 eV or more and smaller than the absolute value of the difference between the HOMO levels of the first layer and the second layer, and more preferably 0.1 eV or more and less than 3.0 eV.

By having the above structure, the number of ground-state molecules gets fewer than that of excited-state molecules in a light-emitting region when holes or electrons are injected into the first layer and the second layer. In other words, an inverted distribution state is formed easily. An element which emits light by injecting holes or electrons in this way is referred to as a current-excitation light-emitting element.

Moreover, in order to amplify light emitted in a region where an inverted distribution state is formed, a light-emitting element of the present invention has a structure for resonating the emitted light.

Specifically, a light-emitting element of the present invention has two layers which are mentioned above between a pair of reflectors, wherein the distance between the reflectors is integral multiplication of ½ of a wavelength of light emitted in a region where an inverted distribution state is formed.

The reflector can serve as an electrode of the light-emitting element.

As a substance for forming the first layer of the light-emitting element, for example, the following is preferably used: 4,4′-bis[N-(1-naphthyl)-N-phenyl-amino]biphenyl (hereinafter abbreviated to α-NPD), 4,4′,4″-tris(N,N-diphenyl-amino)-triphenylamine (hereinafter abbreviated to TDATA), 4,4′-bis[N-(3-methylphenyl)-N-phenylamino]-biphenyl (hereinafter abbreviated to TPD), 4,4′,4″-tris(N-carbazolyl) triphenylamine (hereinafter abbreviated to TCTA), or the like. Moreover, a substance other than the above-mentioned substance can be used as long as the hole mobility is 1×10⁻⁶ cm²/V·sec or more. The mobility is a value measured at room temperature.

As a substance for forming the second layer of the light-emitting element, for example a metal complex having a quinoline skeleton or a benzoquinoline skeleton or a mixed ligand complex thereof, which is typified by tris(8-quinolinolato)aluminum complex (hereinafter abbreviated to Alq₃), or the like is preferable. Moreover, in addition to the metal complex, an oxadiazole derivative such as 2-(4-biphenylyl)-5-(4-tert-butylphenyl)-1,3,4-oxadiazole (hereinafter abbreviated to PBD), or 1,3-bis[5-(p-tert-butylphenyl)-1,3,4-oxadiazole-2-yl]benzene (hereinafter abbreviated to OXD-7); a triazole derivative such as 3-(4-tert-butylphenyl)-4-phenyl-5-(4-biphenylyl)-1,2,4-triazole (hereinafter abbreviated to TAZ), or 3-(4-tert-butylphenyl)-4-(4-ethylphenyl)-5-(4-biphenylyl)-1,2,4-triazole (hereinafter abbreviated to p-EtTAZ); a phenanthroline derivative such as bathophenanthroline (hereinafter abbreviated to BPhen) or bathocuproin (hereinafter abbreviated to BCP); or 4,4′-(N-carbazolyl)biphenyl (hereinafter abbreviated to CBP) can be used. A substance other than the above-mentioned substance can be used as long as the electron mobility is 1×10⁻⁸ cm²/V·sec or more. This mobility is a value measured at room temperature.

One or both of the first layer and the second layer may include an inorganic compound.

In such a light-emitting element, the change of light emission spectrum intensity with respect to the density of current to be fed into the light-emitting element can be sorted out into two linear regions with different slopes. A region where the slope is large is on a high current density side with respect to a region where the slope is small. Then, the thresholds of the two linear regions with different slopes are 2 A/cm² or more and 50 mA/cm² or less.

According to the present invention, a light-emitting element in which an inverted distribution state can be formed by exciting an organic compound with current at low current density can be obtained. Moreover, a light-emitting element in which stimulated-and-emitted light can be resonated/amplified in the region where the inverted distribution state is formed can be obtained. A laser apparatus of a current excitation type using an organic compound as a laser medium can be obtained.

### BRIEF DESCRIPTION OF THE DRAWINGS

In the accompanying drawings:

FIG. 1 shows an energy band structure of a light-emitting element of the present invention;

FIG. 2 shows a multilayer structure of a light-emitting element of the present invention;

FIGS. 3A to 3C show a formation process of an inverted distribution state in a light-emitting element of the present invention;

FIG. 4 shows a multilayer structure of a light-emitting element of the present invention;

FIG. 5 shows an energy band structure of a light-emitting element of the present invention;

FIG. 6 shows a light-emission spectrum of a light-emitting element of the present invention;

FIG. 7 shows current density dependency of light emission spectrum intensity in a light-emitting element of the present invention and a light-emitting element of, a comparative example;

FIG. 8 shows a multilayer structure of a light-emitting element of a comparative example;

FIG. 9 shows a semiconductor laser of a conventional technique;

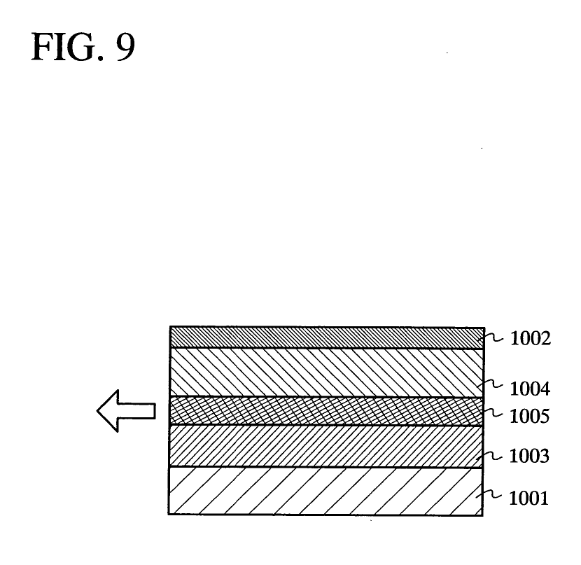

FIG. 10 shows an energy band structure of a light-emitting element of a comparative example; and

FIG. 11 shows a light-emission spectrum of a light-emitting element of a comparative example.

### DETAILED DESCRIPTION OF THE INVENTION

### Embodiment Mode

An embodiment mode of a light-emitting element of the present invention will be hereinafter described.

In a conventional laser element, inverted distribution is obtained by exciting ground-state molecules into excited-state molecules by external energy to make the number of ground-state molecules larger than that of excited-state molecules. In contrast, in the present invention, inverted distribution is formed in such a way that a ground-state molecule is made in a state having a carrier electrochemically to decrease the number of ground-state molecules relatively, thereby making the number of excited-state molecules larger than that of ground-state molecules.

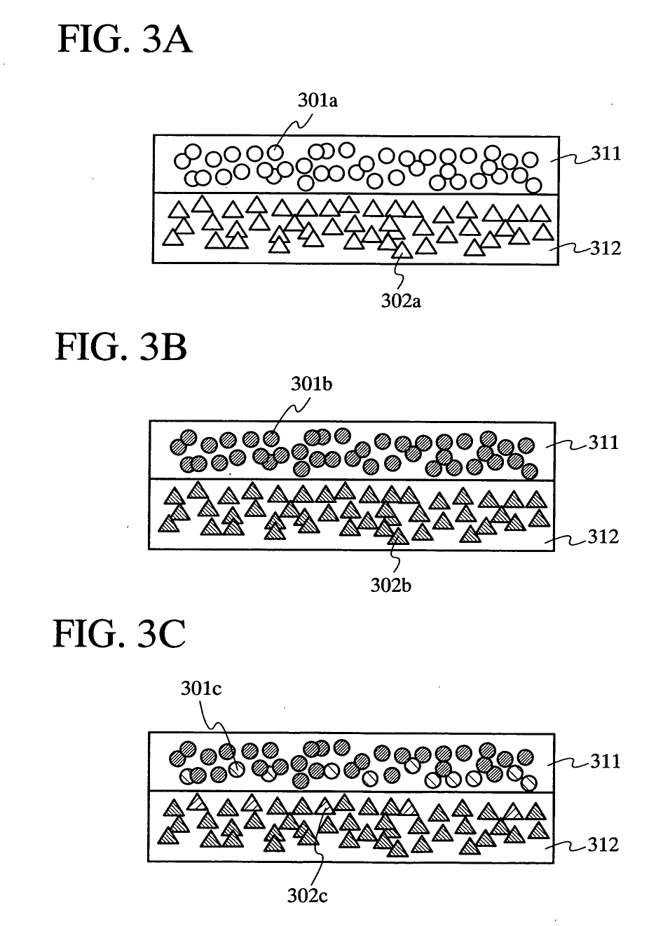

Specifically, as shown in FIGS. 3A to 3C, a light-emitting element has at least two layers 311 and 312 provided adjacently which include molecules 301a and 302a respectively and in each of which the polarity of carriers to be transported preferentially is different. By injecting holes or electrons in each of the two layers 311 and 312, almost all of the molecules 301a and 302a which were in a ground state are made in a state having carriers. The state having carriers means a state where ion species are formed. As the ion species, there are cation radicals 301b and anion radicals 302b. As another ion species, dication, dianion, and the like are given. The formation of the ion species decreases the concentration of the ground-state molecules in the film electrochemically. Then, for example, electrons are injected into a region where almost all of the molecules 301a which were in a ground state have turned into the cation radicals 301b. At this time, excited-state molecules 301c are formed by recombination; however, since the density of the ground-state molecules 301a is very low, the number of excited-state molecules 301c becomes relatively larger than that of the ground-state molecules 301a, thereby forming an inverted distribution state. In FIG. 3C, a reference numeral 302c denotes a molecule which has returned to a ground state after emitting light.

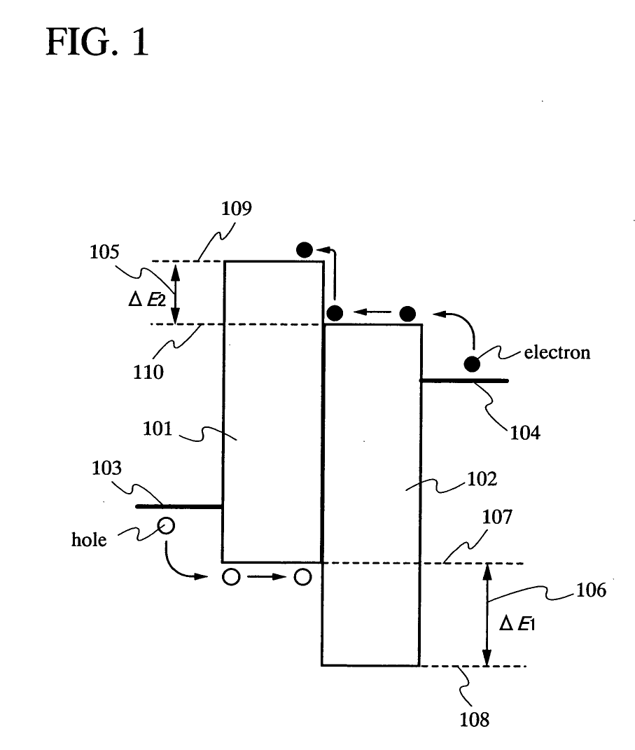

An energy structure of a light-emitting element in which such an electrochemical inverted distribution state can be formed is described with reference to FIG. 1.

FIG. 1 is an energy band diagram of a light-emitting element of the present invention. In FIG. 1, a first layer 101 has a higher hole-transporting property than electron-transporting property, while a second layer 102 has a higher electron-transporting property than hole-transporting property. Holes are injected from an anode 103 side to the first layer 101 and transported to a cathode 104 side.

Here, the first layer 101 and the second layer 102 are formed so that a HOMO level 107 of the first layer 101 is higher than a HOMO level 108 of the second layer 102 and an absolute value of a difference (ΔE₁) 106 between the HOMO levels of the first layer 101 and the second layer 102 is as high as possible. This makes it possible to make the second layer 102 serve as a layer for blocking the holes and to accumulate as many holes as possible in the first layer 101. The absolute value of the difference 106 between the HOMO levels is preferably 0.5 eV or more, more preferably 0.5 eV or more and less than 3.0 eV.

Moreover, the first layer 101 and the second layer 102 are formed so that a LUMO level 109 of the first layer 101 is higher than a LUMO level 110 of the second layer 102 and an absolute value of a difference (ΔE₂) 105 between the LUMO levels of the first layer 101 and the second layer 102 is as high as possible. This makes it possible to prevent a large amount of electrons injected from the cathode 104 side from being injected into the first layer 101. Therefore, it is possible to suppress that the holes cannot be accumulated because of the recombination of the electrons and the holes.

The difference between the HOMO levels or between the LUMO levels is referred to as an energy barrier.

In order to emit light, an energy barrier against electron transportation is set lower than that against hole transportation. In other words, the absolute value of the difference (ΔE₂) 105 between the LUMO levels is smaller than the absolute value of the difference 106 (ΔE₁) between the HOMO levels. This is because the carrier injection speed depends largely on the height of the energy barrier. The difference 105 between the LUMO levels is preferably 0.1 eV or more and less than 3.0 eV. By having such a value, it is possible to control so that electrons are slightly injected into the first layer 101.

In a light-emitting element of the present invention having the above structure, the number of ground-state molecules in a light-emitting region is decreased as much as possible, whereby the density of molecules having holes (cation radical molecules) can be increased. In other words, the ground-state molecule hardly exists in a part of the first layer 101 that is in contact with the second layer 102, and cation radicals, which are ion species, occupy this part. Further, in the first layer 101 where the holes are accumulated, electrons are slightly injected. When the electrons are injected, excitons are generated in the light-emitting region because the electrons are recombined with the holes. In other words, an excited state is formed. At this time, since the ground-state molecule hardly exists in the light-emitting region, the number of ground-state molecules is smaller than that of the excited-state molecules, thereby forming an inverted distribution state.

Although the light-emitting element having a structure in which the inverted distribution state is formed in the first layer 101 is described in this embodiment mode, the light-emitting element may have a structure in which the inverted distribution state is formed in the second layer 102. In the latter case, the light-emitting element may have a structure which is completely opposite of that of the above light-emitting element. Specifically, the absolute value of ΔE₂ is larger than that of ΔE₁. In the light-emitting element having such a structure, electrons are accumulated in the second layer 102.

Many of organic compounds have a higher hole-transporting property than electron-transporting property. It is easier to manufacture a light-emitting element having higher hole mobility of the first layer 101 than electron mobility of the second layer 102. Therefore, the light-emitting element preferably has a structure in which the inverted distribution state is formed in the first layer 101 as described above.

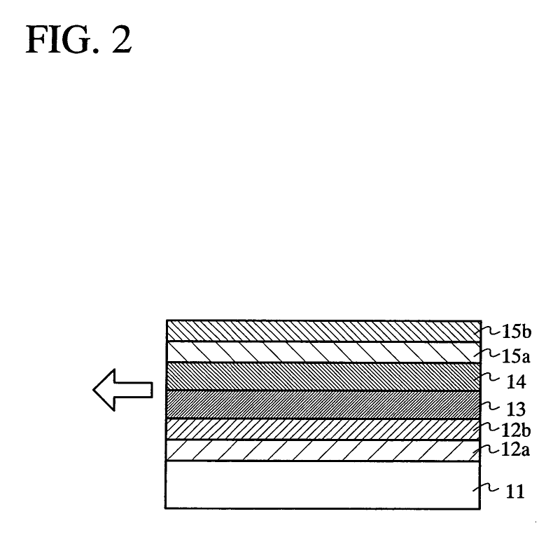

A structure of a light-emitting element having the above-described energy band structure will be hereinafter described with reference to FIG. 2.

This embodiment mode will describe a light-emitting element having a structure in which light emission can be taken out from an edge surface (edge portion) of the light-emitting element as indicated by an arrow. In addition, even a light-emitting element having a structure in which light emission is taken out from a top surface of the light-emitting element can employ an element structure of the present invention.

In FIG. 2, a reference numeral 11 denotes a substrate for supporting an element. A material of the substrate 11 is not particularly limited. Not only glass, quartz, and plastic but also flexible materials such as paper and cloth can be used for the substrate.

Over the substrate 11, a first electrode 12 is formed. The first electrode 12 preferably serves as a reflector for reflecting emitted light as well as an anode. In the light-emitting element shown in this embodiment mode, the first electrode 12 can be formed with two layers (12a and 12b). For example, the first electrode 12a may be formed with a material having a high conductive property. Moreover, the first electrode 12b is in contact with a first layer 13 and is formed with a material having a function to inject holes into the first layer 13. For example, a metal oxide having high work function such as ITO (indium tin oxide) or ZnO can be used. Moreover, the first electrode 12b preferably serves as a reflector. Therefore, it is preferable to form the first electrode 12b with metal having reflectivity and a high work function, such as Al, Ag, Pt, or Au, alloy, or the like. Because, considering that the first electrode 12b also serves as a reflector, it is preferable to use a material having high reflectivity and a low absorption ratio of visible light, like Ag. The film thickness is also controlled so that the first electrode 12b can serve as a reflector because the first electrode 12b cannot serve as a reflector if the film thickness is very small. Since the first electrode 12b is formed with a material having a high work function, the work function of the first electrode 12a is not particularly limited. The first electrode 12a may be formed with a material having reflectivity (such as Al or Ag), and a dielectric multilayer film or the like may be used. When the electrode is formed by stacking layers in this way, the range of choices for an electrode material can be expanded, thereby increasing the respective functions of the stacked electrodes. The first electrode 12 is not necessarily formed with two layers, and a single-layer structure or a multilayer structure of three or more layers may be employed.

The first layer 13 formed on the first electrode 12b serves as a layer for emitting light as well as a layer for transporting holes. In the light-emitting element of this embodiment mode, it is preferable to form the first layer 13 with a material having a higher hole-transporting property than electron-transporting property, a high hole-injecting property, and a large energy band gap. Moreover, in order to emit light, the first layer is preferably formed with a material having high quantum yield of light emission. For example, aromatic amine is preferable. Specifically, 4,4′-bis[N-(1-naphthyl)-N-phenyl-amino]-biphenyl (hereinafter abbreviated to α-NPD), 4,4+,4″-tris (N,N-diphenyl-amino)-triphenylamine (hereinafter abbreviated to TDATA), 4,4′-bis[N-(3-methylphenyl)-N-phenylamino]-biphenyl (hereinafter abbreviated to TPD), 4,4′4″-tris(N-carbazolyl)triphenylamine (hereinafter abbreviated to TCTA), or the like can be used. Meanwhile, poly(vinyl carbazole) exhibiting a favorable hole-transporting property or the like may be used as a polymer material. It is to be noted that a triphenylamine derivative is particularly preferable because the energy band gap is large and the HOMO level is high, in other words, the ionizing potential is low. The first layer 13 may have not only a single-layer structure but also a multilayer structure of two or more layers formed with the above-mentioned substance.

A HOMO level of the first layer 13 is preferably higher than a HOMO level of the second layer 14 and a LUMO level of the first layer 13 is preferably higher than a LUMO level of the second layer 14. When the first layer 13 has a multilayer structure of two or more layers, a HOMO lever and a LUMO lever of a layer in the first layer 13 which is in contact with the second layer 14 are preferably higher than the HOMO level and the LUMO level of the second layer 14, respectively. When the second layer 14 has a multilayer structure of two or more layers, a LUMO level and a LUMO level of a layer in the second layer 14 which is in contact with the first layer 13 are preferably higher than the HOMO level and the LUMO level of the first layer 13, respectively. When each of the first layer 13 and the second layer 14 has a multilayer structure of two or more layers, a HOMO level and a LUMO level of a layer in the first layer 13 which is in contact with the second layer 14 are preferably higher than a HOMO level and a LUMO level of a layer in the second layer 14 which is in contact with the first layer 13, respectively.

A second layer 14 is formed on the first layer 13. The second layer serves as a layer for transporting electrons. It is preferable to form the second layer 14 with a material having a higher electron-transporting property than hole-transporting property, a high electron-injecting property, and high ionizing potential. For example, a metal complex having a quinoline skeleton or a benzoquinoline skeleton, a mixed ligand complex thereof, or the like, which is typified by tris(8-quinolinolato)aluminum complex (hereinafter abbreviated to Alq₃) is preferably used. Moreover, other than the metal complex, an oxadiazole derivative such as 2-(4-biphenylyl)-5-(4-tert-buthylphenyl)-1,3,4-oxadiazole (hereinafter abbreviated to PBD) or 1,3-bis[5-(p-tert-buthylphenyl)-1,3,4-oxadiazole-2-yl]benzene (hereinafter abbreviated to OXD-7); a triazole derivative such as 3-(4-tert-buthylphenyl)-4-phenyl-5-(4-biphenylyl)-1,2,4-triazole (hereinafter abbreviated to TAZ) or 3-(4-tert-buthylphenyl)-4-(4-ethylphenyl)-5-(4-biphenylyl)-1,2,4-triazole (hereinafter abbreviated to p-EtTAZ); a phenanthroline derivative such as bathophenanthroline (hereinafter abbreviated to BPhen) or bathocuproine (hereinafter abbreviated to BCP); or 4,4′-(N-carbazolyl)biphenyl (hereinafter abbreviated to CBP) can be used. It is to be noted that a substance for forming the second layer 14 preferably has a larger band gap and much higher ionizing potential than a substance for forming the first layer 13. Specifically, a carbazole derivative, a phenanthroline derivative such as CBP or BCP, or the like is given. The second layer 14 may have not only a single-layer structure but also a multilayer structure including two or more layers formed with the above-mentioned substance.

A second electrode 15 is formed on the second layer 14. The second electrode 15 preferably serves as a reflector for reflecting emitted light as well as a cathode. In the light-emitting element shown in this embodiment mode, the second electrode 15 can be formed with two layers (15a and 15b). For example, the second electrode 15a is in contact with the second layer 14 and injects electrons to the second layer 14. Therefore, the second electrode 15a is preferably formed with a material having a low work function such as a typical element belonging to Group 1 or 2, i.e., alkali metal such as Li or Cs, alkali-earth metal such as Mg, Ca, or Sr, or alloy including any one of these such as Mg/Ag or Al/Li, or transition metal including rare-earth metal. The second electrode 15a serves as a reflector. Therefore, it is preferable to form the second electrode 15a with metal having high reflectivity and little absorption of visible light, such as Al, Ag, or Mg, or alloy including any one of these. The film thickness is controlled so that the second electrode 15a can serve as a reflector, because the second electrode 15a cannot serve as a reflector if the film thickness is very small. Since the second electrode 15a is formed with a material having a low work function, the work function of the second electrode 15b is not particularly limited. The second electrode 15b may be formed with a material having reflectivity (such as Al or Ag), and a dielectric multilayer film or the like may be used. By thus forming the electrode in the multilayer structure, the range of choices for an electrode material can be expanded, thereby improving the respective functions of the stacked electrodes. The second electrode 15 is not necessarily formed with two layers, and either a single-layer structure or a multilayer structure including three or more layers may be employed.

The first layer 13 and the second layer 14 may be formed by either a wet or dry method. In the case of the polymer material, a spin coating method, an ink-jet method, a dip coating method, a printing method, or the like is appropriate. Meanwhile, in the case of a low-molecular-weight material, not only a dip coating method or a spin coating method but also vacuum evaporation or the like can be employed. The formation methods of the first electrode 12 and the second electrode 15 are not particularly limited, and an evaporation method, a sputtering method, or the like may be employed.

An optical distance between the first electrode 12 and the second electrode 15 serving as reflectors (this optical distance is hereinafter referred to as a distance simply) is preferably integral multiplication of ½ of an oscillation wavelength in order to resonate/amplify light emitted in a region where an inverted distribution state is formed, because this can form a standing wave to resonate/amplify light. Moreover, the distance can be controlled by changing the sum of the film thicknesses of the first layer 13 and the second layer 14.

In this embodiment mode, the layer provided between the first electrode 12 and the second electrode 15 includes two layers of the first layer 13 and the second layer 14; however, the present invention is not limited to this, and three or more layers including another functional layer may be formed. For example, an electron-injecting layer, a hole-injecting layer, a hole-blocking layer, or the like may be provided.

In the above light-emitting element, as will be shown in Embodiment 1 later, a threshold of stimulated emission which can be seen from the change of light emission intensity with respect to current density can be made at a current density of 50 mA/cm² or less, preferably 15 mA/cm² or less. In other words, an inverted distribution state is formed in the case of feeding current so that the current density is the same as or more than this threshold. The threshold is preferably 2 mA/cm² or more and 50 mA/cm² or less in consideration of the endurance of the light-emitting element, and the threshold can be made at 2 mA/cm² or more and 50 mA/cm² or less in the light-emitting element of the present invention. In a region where such a state is formed, a part of emitted light generated by recombination of electrons and holes injected from the respective electrodes is resonated/amplified between the reflectors (the first and second electrodes in this embodiment mode). A light emission spectrum of the light has a main oscillation wavelength which can be resonated within the light-emitting element and has a relatively sharp peak. The above light-emitting element can be used as a laser oscillator, i.e., a laser apparatus.

### Embodiment 1

A light-emitting element of the present invention and some characteristics of the light-emitting element will be described.

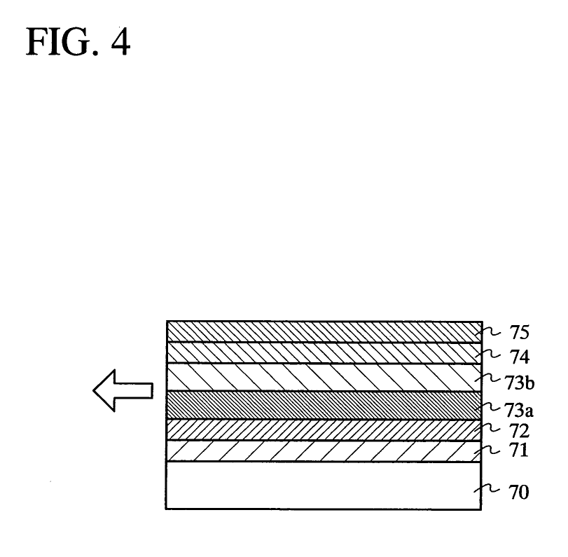

As shown in FIG. 4, an electrode 71 is formed by forming ITO over a glass substrate 70. After forming a-NPD as a first layer 72 on the electrode 71 by vacuum evaporation, CBP and BCP are sequentially stacked as second layers 73 (73a and 73b) on the first layer 72. After forming calcium fluoride as a third layer 74 on the second layer 73, aluminum is formed as an electrode 75, thereby forming a light-emitting element. The film thicknesses of the first layer 72 and the second layers 73a and 73b are respectively 100 nm, 30 nm, and 130 nm, and the total film thickness is 260 nm. In the above light-emitting element, the electrodes 71 and 75 respectively serve as reflectors. In this way, the light-emitting element in this embodiment has a structure for resonating emitted light.

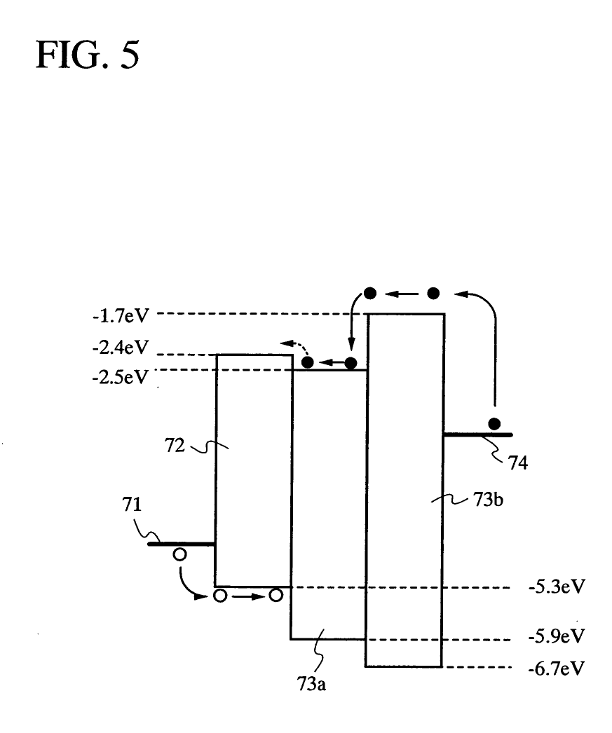

It is noted that a-NPD is superior in a hole-transporting property with a LUMO level of −2.4 eV and a HOMO level of −5.3 eV. CBP has a high electron-transporting property with a LUMO level of −2.5 eV and a HOMO level of −5.9 eV. BCP is superior in an electron-transporting property with a LUMO level of −1.7 eV and a HOMO level of −6.7 eV. An energy band structure of the above light-emitting element is shown in FIG. 5. As is clear from FIG. 5, the LUMO level of the first layer 72 is higher than the LUMO level of the second layer 73a. Moreover, the HOMO level of the first layer 72 is higher than the HOMO level of the second layer 73a. Further, the LUMO level of the second layer 73b is higher than the LUMO level of the second layer 73a and the HOMO level of the second layer 73b is lower than the HOMO level of the second layer 73a.

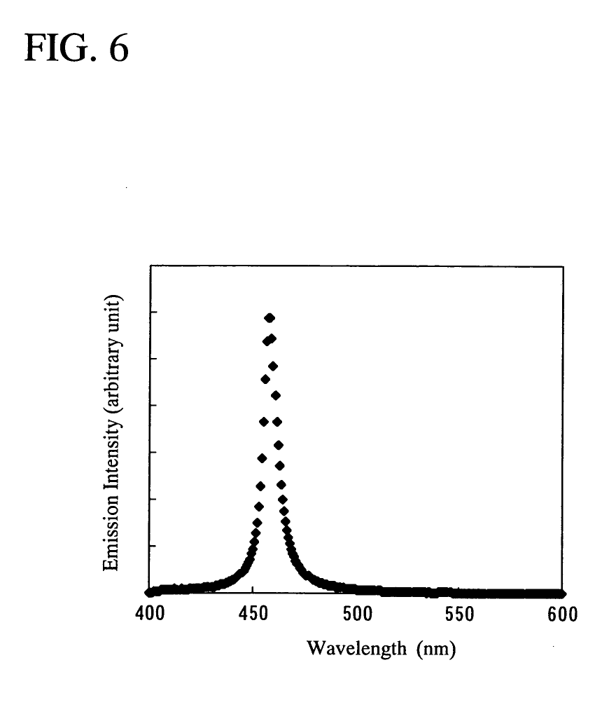

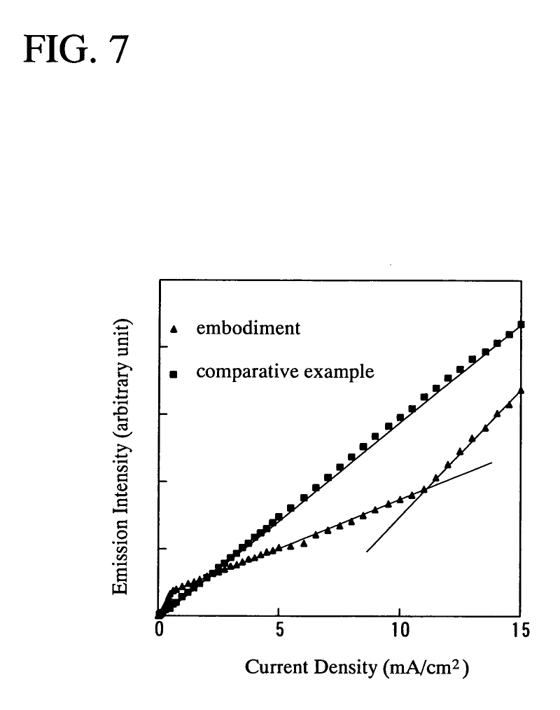

FIG. 6 shows a light emission spectrum of the above light-emitting element. It is understood from FIG. 6 that the light emission with a peak having narrow width at half maximum at 0465 nm is obtained. Moreover, change of light emission intensity with respect to current density is shown in FIG. 7. Plots in this embodiment are sorted out into two regions with different slopes and approximate lines on the respective regions are shown with solid lines. It is understood from FIG. 7 that the light emission intensity increases linearly in accordance with the increase in the current density and the slope becomes larger from a current density of 12 mA/cm² as a folding point (or a threshold). It is considered that this is because natural emission is dominant in a region having a current density less than 12 mA/cm² while stimulated emission occurs in a region having a current density more than 12 mA/cm².

Moreover, this is considered to result from the following mechanism. Holes injected into the first layer are prevented from being injected into the second layer 73a by an energy barrier between the first layer 72 and the second layer 73a (a difference between the HOMO levels) and are accumulated in the first layer 72. Electrons injected easily from the second layer 73b into the second layer 73a are prevented from being injected into the first layer 72 by an energy barrier between the first layer 72 and the second layer 73a (a difference between the LUMO levels). However, the electrons are injected into the first layer though the probability is very low. Therefore, in a region of the first layer 72 that is on the second layer 73a side, the electrons and the holes are recombined to form an excited state. However, since the region has high concentration of molecules having holes, the number of excited-state molecules is larger than that of ground-state molecules, thereby forming an inverted distribution state.

### COMPARATIVE EXAMPLE

A comparative example to the above light-emitting element will be described.

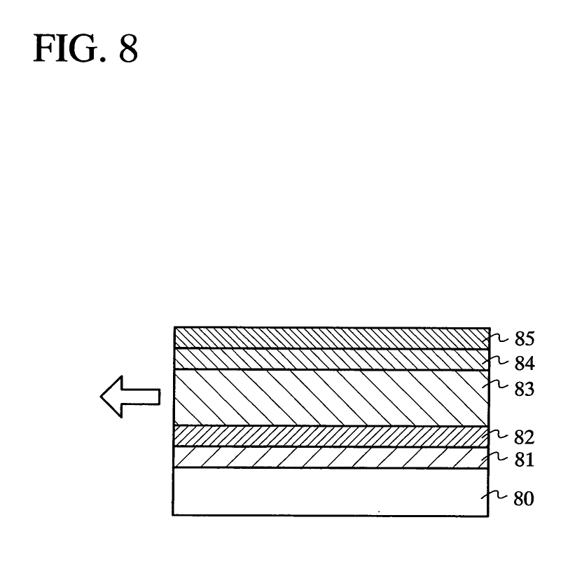

As shown in FIG. 8, an electrode 81 is formed by forming ITO over a glass substrate 80. After forming α-NPD as a first layer 82 on the electrode 81 by vacuum evaporation, BCP is formed as a second layer 83 on the first layer 82. After forming calcium fluoride as a third layer 84 on the second layer 83, aluminum is formed as an electrode 85, thereby forming a light-emitting element. The film thicknesses of the first layer 82 and the second layer 83 are respectively 100 nm and 160 nm, and the total thickness is 260 nm. In the light-emitting element, the electrodes 81 and 84 respectively serve as reflectors. The light-emitting element in this comparative example has a structure in which emitted light can be resonated.

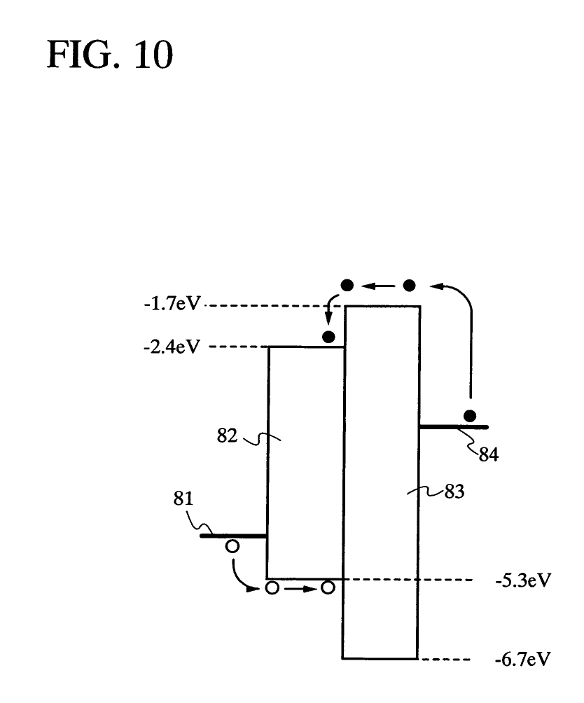

An energy band structure of the light-emitting element in the comparative example is shown in FIG. 10. As is clear from FIG. 10, the LUMO level of the first layer 82 is lower than the LUMO level of the second layer 83. Further, the HOMO level of the first layer 82 is higher than the HOMO level of the second layer 83.

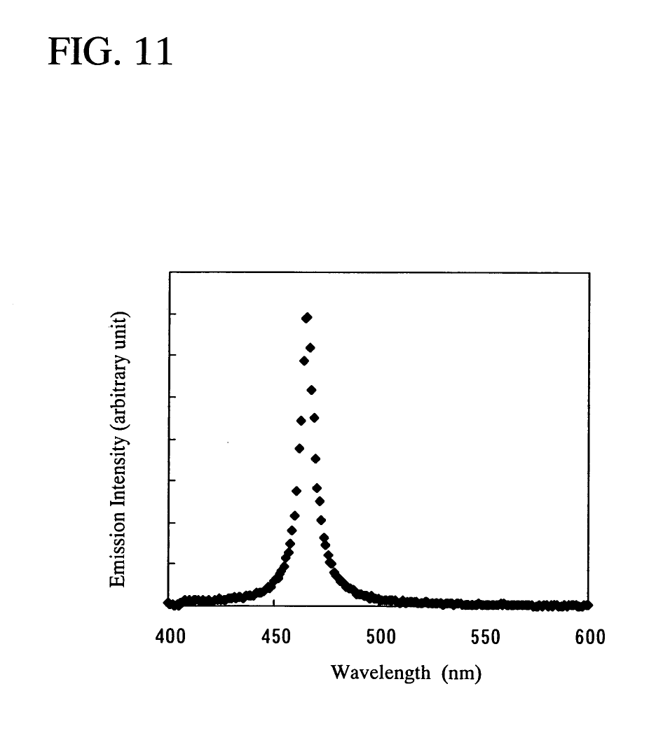

A light emission spectrum of the light-emitting element is shown in FIG. 11. It is understood from FIG. 11 that light emission with a peak having narrow width at half maximum at 460 nm is obtained. However, it is understood from FIG. 7 showing the dependency of the light emission intensity to the current density that the light emission intensity linearly increases in accordance with the increase in the current density; however, a folding point does not appear, differently from the light-emitting element of the present invention.

It is considered that this results from the following mechanism. Holes injected into the first layer are prevented from being injected into the second layer 83 by an energy barrier between the first layer 82 and the second layer 83 (a difference between the HOMO levels) and accumulated in the first layer 82. However, since the LUMO level is higher in the second layer 83 than in the first layer 82, electrons are injected immediately from the second layer 83 into the first layer 82, which causes the electrons and holes to be recombined often. As a result, the number of molecules having carriers is small, and the number of molecules having returned to the ground state is larger than that of excited-state molecules. Thus, an inverted distribution state cannot be formed.

1. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer.

2. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer, and wherein energy barriers exist between a LUMO level of the first layer and a LUMO level of the second layer and between a HOMO level of the first layer and a HOMO level of the second layer, respectively.

3. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer,
wherein energy barriers exist between a LUMO level of the first layer and a LUMO level of the second layer and between a HOMO level of the first layer and a HOMO level of the second layer, respectively, and
wherein the energy barrier between the HOMO level of the first layer and the HOMO level of the second layer is higher than the energy barrier between the LUMO level of the first layer and the LUMO level of the second layer.

4. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer, and
wherein a proportion of molecules existing in a ground state in a region of the first layer that is in contact with the second layer is electrochemically decreased to make a proportion of molecules in an excited state larger than a proportion of the molecules in the ground state, thereby generating an inverted distribution state.

5. A light-emitting element comprising a first layer and a second layer between a pair of electrodes,
wherein the first layer and the second layer being provided adjacently so that when a hole is injected into one of the first layer and the second layer and an electron is injected into the other of the first layer and the second layer, ion species are accumulated in a region of the first layer that is in contact with the second layer;
a first energy barrier for blocking movement of the hole from the first layer to the second layer; and
a second energy barrier for blocking movement of the electron from the second layer to the first layer.

6. A light-emitting element comprising a first layer and a second layer between a pair of electrodes,
wherein the first layer and the second layer being provided adjacently so that when a hole is injected into one of the first layer and the second layer and an electron is injected into the other of the first layer and the second layer, ion species are accumulated in a region of the first layer that is in contact with the second layer;
a first energy barrier for blocking movement of the hole from the first layer to the second layer; and
a second energy barrier for blocking movement of the electron from the second layer to the first layer;
wherein the first energy barrier is higher than the second energy barrier.

7. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer,
wherein polarity of a carrier to be transported preferentially is different for each of the first layer and the second layer,
wherein a HOMO level of the first layer is higher than a HOMO level of the second layer, and
wherein a LUMO level of the first layer is higher than a LUMO level of the second layer.

8. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer,
wherein the first layer has higher hole mobility than electron mobility,
wherein the second layer has higher electron mobility than hole mobility,
wherein a HOMO level of the first layer is higher than a HOMO level of the second layer, and
wherein a LUMO level of the first layer is higher than a LUMO level of the second layer.

9. The light-emitting element according to claim 7,
wherein an absolute value of a difference between the HOMO levels of the first layer and the second layer is 0.5 eV or more.

10. The light-emitting element according to claim 7,
wherein an absolute value of a difference between the HOMO levels of the first layer and the second layer is larger than an absolute value of a difference between the LUMO levels of the first layer and the second layer.

11. The light-emitting element according to claim 10,
wherein an absolute value of a difference between the LUMO levels of the first layer and the second layer is 0.1 eV or more and less than 3.0 eV.

12. A light-emitting element according to claim 1, further comprising:
a first electrode and a second electrode for reflecting light emitted from the light-emitting element,
wherein the first layer and the second layer have film thicknesses for resonating the light at the first electrode and the second electrode.

13. The light-emitting element according to claim 5,
wherein the first layer is formed with 4,4′-bis[N-(1-naphthyl)-N-phenyl-amino]-biphenyl.

14. The light-emitting element according to claim 5,
wherein the second layer is formed with 4,4′-(N-carbazolyl)biphenyl.

15. The light-emitting element according to claim 5,
wherein the second layer is formed with 4,4′-(N-carbazolyl)biphenyl and bathocuproin.

16. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer, and
wherein changes of light emission spectrum intensity with respect to current density are sorted out into two linear regions with different slopes, and a region where the slope is large is on a high current density side with respect to a region where the slope is small.

17. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer,
wherein energy barriers exist between a LUMO level of the first layer and a LUMO level of the second layer and between a HOMO level of the first layer and a HOMO level of the second layer, respectively, and
wherein changes of light emission spectrum intensity with respect to current density are sorted out into two linear regions with different slopes, and a region where the slope is large is on a high current density side with respect to a region where the slope is small.

18. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer,
wherein energy barriers exist between a LUMO level of the first layer and a LUMO level of the second layer and between a HOMO level of the first layer and a HOMO level of the second layer, respectively,
wherein the energy barrier between the HOMO level of the first layer and the HOMO level of the second layer is higher than the energy barrier between the LUMO level of the first layer and the LUMO level of the second layer, and
wherein changes of light emission spectrum intensity with respect to current density are sorted out into two linear regions with different slopes, and a region where the slope is large is on a high current density side with respect to a region where the slope is small.

19. A light-emitting element comprising a first layer and a second layer between a pair of electrodes,
wherein the first layer and the second layer are provided adjacently so that when a hole is injected into one of the first layer and the second layer and an electron is injected into the other of the first layer and the second layer, ion species are accumulated in a region of the first layer that is in contact with the second layer,
wherein a proportion of molecules existing in a ground state in a region of the first layer that is in contact with the second layer is electrochemically decreased to make a proportion of molecules in an excited state larger than a proportion of the molecules in the ground state, thereby generating an inverted distribution state, and
wherein changes of light emission spectrum intensity with respect to current density are sorted out into two linear regions with different slopes, and a region where the slope is large is on a high current density side with respect to a region where the slope is small.

20. The light-emitting element according to claim 16,
wherein thresholds of the two linear regions with different slopes are 2 mA/cm² or more and less than 50 mA/cm².

21. A laser apparatus using the light-emitting element according to claim 1.

22. A laser apparatus using the light-emitting element according to claim 1 as a laser oscillator.

23. The light-emitting element according to claim 8,
wherein an absolute value of a difference between the HOMO levels of the first layer and the second layer is 0.5 eV or more.

24. The light-emitting element according to claim 8,
wherein an absolute value of a difference between the HOMO levels of the first layer and the second layer is larger than an absolute value of a difference between the LUMO levels of the first layer and the second layer.

25. The light-emitting element according to claim 24,
wherein the absolute value of the difference between the LUMO levels of the first layer and the second layer is 0.1 eV or more and less than 3.0 eV.

26. A light-emitting element according to claim 2, further comprising:
a first electrode and a second electrode for reflecting light emitted from the light-emitting element,
wherein the first layer and the second layer have film thicknesses for resonating the light at the first electrode and the second electrode.

27. A light-emitting element according to claim 3, further comprising:
a first electrode and a second electrode for reflecting light emitted from the light-emitting element,
wherein the first layer and the second layer have film thicknesses for resonating the light at the first electrode and the second electrode.

28. A light-emitting element according to claim 4, further comprising:
a first electrode and a second electrode for reflecting light emitted from the light-emitting element,
wherein the first layer and the second layer have film thicknesses for resonating the light at the first electrode and the second electrode.

29. A light-emitting element according to claim 5, further comprising:
a first electrode and a second electrode for reflecting light emitted from the light-emitting element,
wherein the first layer and the second layer have film thicknesses for resonating the light at the first electrode and the second electrode.

30. A light-emitting element according to claim 6, further comprising:
a first electrode and a second electrode for reflecting light emitted from the light-emitting element,
wherein the first layer and the second layer have film thicknesses for resonating the light at the first electrode and the second electrode.

31. The light-emitting element according to claim 6,
wherein the first layer is formed with 4,4′-bis[N-(1-naphthyl)-N-phenyl- amino]-biphenyl.

32. The light-emitting element according to claim 6, wherein the second layer is formed with 4,4′-(N-carbazolyl)biphenyl.

33. The light-emitting element according to claim 6,
wherein the second layer is formed with 4,4′-(N-carbazolyl)biphenyl and bathocuproin.

34. A light-emitting element according to claim 7, further comprising:
a first electrode and a second electrode for reflecting light emitted from the light-emitting element,
wherein the first layer and the second layer have film thicknesses for resonating the light at the first electrode and the second electrode.

35. The light-emitting element according to claim 7,
wherein the first layer is formed with 4,4′-bis[N-(1-naphthyl)-N-phenyl-amino]-biphenyl.

36. The light-emitting element according to claim 7,
wherein the second layer is formed with 4,4′-(N-carbazolyl)biphenyl.

37. The light-emitting element according to claim 7,
wherein the second layer is formed with 4,4′-(N-carbazolyl)biphenyl and bathocuproin.

38. A light-emitting element according to claim 8, further comprising:
a first electrode and a second electrode for reflecting light emitted from the light-emitting element,
wherein the first layer and the second layer have film thicknesses for resonating the light at the first electrode and the second electrode.

39. The light-emitting element according to claim 8,
wherein the first layer is formed with 4,4′-bis[N-(1-naphthyl)-N-phenyl-amino]-biphenyl.

40. The light-emitting element according to claim 8, wherein the second layer is formed with 4,4′-(N-carbazolyl)biphenyl.

41. The light-emitting element according to claim 8,
wherein the second layer is formed with 4,4′-(N-carbazolyl)biphenyl and bathocuproin.

42. The light-emitting element according to claim 17,
wherein thresholds of the two linear regions with different slopes are 2 mA/cm² or more and less than 50 mA/cm².

43. The light-emitting element according to claim 18,
wherein thresholds of the two linear regions with different slopes are 2 mA/cm² or more and less than 50 mA/cm².

44. The light-emitting element according to claim 19,
wherein thresholds of the two linear regions with different slopes are 2 mA/cm² or more and less than 50 mA/cm².

45. A laser apparatus using the light-emitting element according to claim 2.

46. A laser apparatus using the light-emitting element according to claim 2 as a laser oscillator.

47. A laser apparatus using the light-emitting element according to claim 3.

48. A laser apparatus using the light-emitting element according to claim 3 as a laser oscillator.

49. A laser apparatus using the light-emitting element according to claim 4.

50. A laser apparatus using the light-emitting element according to claim 4 as a laser oscillator.

51. A laser apparatus using the light-emitting element according to claim 5.

52. A laser apparatus using the light-emitting element according to claim 5 as a laser oscillator.

53. A laser apparatus using the light-emitting element according to claim 6.

54. A laser apparatus using the light-emitting element according to claim 6 as a laser oscillator.

55. A laser apparatus using the light-emitting element according to claim 7.

56. A laser apparatus using the light-emitting element according to claim 7 as a laser oscillator.

57. A laser apparatus using the light-emitting element according to claim 8.

58. A laser apparatus using the light-emitting element according to claim 8 as a laser oscillator.

59. A laser apparatus using the light-emitting element according to claim 16.

60. A laser apparatus using the light-emitting element according to claim 16 as a laser oscillator.

61. A laser apparatus using the light-emitting element according to claim 17.

62. A laser apparatus using the light-emitting element according to claim 17 as a laser oscillator.

63. A laser apparatus using the light-emitting element according to claim 18.

64. A laser apparatus using the light-emitting element according to claim 18 as a laser oscillator.

65. A laser apparatus using the light-emitting element according to claim 19.

66. A laser apparatus using the light-emitting element according to claim 19 as a laser oscillator.
